(19) United States
(12) Patent Application Publication
(10) Pub. No.: US 2025/0311283 A1
(43) Pub. Date: Oct. 2, 2025

(54) SELECTIVE CHANNEL WIDTH SCALING USING IMPLANTS

(71) Applicant: Intel Corporation, Santa Clara, CA (US)

(72) Inventors: Rahul Pandey, Hillsboro, OR (US); Rahul Ramamurthy, Hillsboro, OR (US); Jubin Nathawat, Hillsboro, OR (US); Yang Cao, Beaverton, OR (US); Jae Hur, Hillsboro, OR (US); Anant H. Jahagirdar, Portland, OR (US); Michael L. Hattendorf, Portland, OR (US); Owen Y. Loh, Portland, OR (US); Paul A. Packan, Hillsboro, OR (US); Yanbin Luo, Portland, OR (US); Inanc Meric, Hillsboro, OR (US); Jeffrey Hicks, Banks, OR (US); David J. Towner, Portland, OR (US)

(21) Appl. No.: 18/621,812

(22) Filed: Mar. 29, 2024

(51) Int. Cl. H01L 29/78; H01L 21/8234; H01L 27/088; H01L 29/167; H01L 29/775; H01L 29/786

(52) U.S. Cl. CPC H10D 30/6213; H10D 30/43; H10D 30/6757; H10D 62/834; H10D 84/0128; H10D 84/0158; H10D 84/038; H10D 84/834

(57) ABSTRACT

An integrated circuit includes a source region and a drain region, and a body including semiconductor material extending between the source and drain regions. The body has first and second end portions, and a middle portion between the first and second end portions. The body includes an implant species, a concentration of the implant species in the middle portion of the body being 10% or more higher than a concentration of the implant species in the first and second end portions. The integrated circuit includes a gate structure on the middle portion of the body, a first gate spacer on the first end portion of the body, and a second gate spacer on the second end portion of the body. The implant species includes, for example, a non-dopant element having an atomic mass unit of 80 or less, or a halide, e.g., one of fluorine, chlorine, argon, or boron.

### FIELD OF THE DISCLOSURE

The present disclosure relates to integrated circuits, and more particularly, to fin-based transistor devices.

### BACKGROUND

A finFET is a transistor built around a thin strip of semiconductor material (generally referred to as the fin). The transistor includes the standard field-effect transistor (FET) nodes, including a gate structure, a source region, and a drain region. The conductive channel of the device resides on the outer portions of the fin adjacent to the gate structure. Specifically, current runs along/within both sidewalls of the fin (sides perpendicular to the substrate surface) as well as along the top of the fin (side parallel to the substrate surface). Because the conductive channel of such configurations essentially resides along the three different outer, planar regions of the fin, such a finFET design is sometimes referred to as a tri-gate transistor. Other types of finFET configurations are also available, such as so-called double-gate finFETs, in which the conductive channel principally resides only along the two sidewalls of the fin (and not along the top of the fin). Another type of transistor is referred to as a gate-all-around transistor that includes nanoribbons or nanowires extending between source and drain regions. In such gate-all-around devices, the gate structure wraps around the nanoribbons or nanowires. The nanoribbons or nanowires are “released” during gate processing, by removing sacrificial layers of a multilayer fin. In any such fin-based transistors, a portion of the fin or fin structure may remain below the gate structure and the source and drain regions. This portion of the fin is generally referred to as a sub-fin.

### BRIEF DESCRIPTION OF THE DRAWINGS

FIGS. 1A, 1B, 1C, and 1D illustrate various views of an integrated circuit (IC) comprising a plurality of devices, each device comprising a corresponding fin, wherein each fin includes a middle portion between two end portions, wherein the middle portion of at least one fin has a different thickness profile and/or tapering profile compared to the two corresponding end portions of the at least one fin, and/or wherein the middle portion of the at least one fin includes an implant species, in accordance with an embodiment of the present disclosure.

FIG. 2 illustrates a graph depicting a variation of a concentration of an implant species along a depth of a middle portion of a fin, in accordance with an embodiment of the present disclosure.

FIG. 3 illustrates a flowchart depicting a method of forming an IC (such as the IC of FIGS. 1A-1D), in accordance with an embodiment of the present disclosure.

FIGS. 4A1, 4A2, 4A3, 4B1, 4B2, 4B3, 4C1, 4C2, 4C3, 4D1, 4D2, 4D3, 4E1, 4E2, and 4E3 illustrate various views of an IC (such as the IC of FIGS. 1A-1D) in various stages of processing in accordance with the methodology of FIG. 3, in accordance with an embodiment of the present disclosure.

FIG. 5 illustrates a computing system implemented with integrated circuit structures formed using the techniques disclosed herein, in accordance with some embodiments of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles (e.g., curved or tapered sidewalls and round corners), and some features may have surface topography or otherwise be non-smooth, given real-world limitations of fabrication processes. Further still, some of the features in the drawings may include a patterned and/or shaded fill, which is merely provided to assist in visually identifying the different features. In short, the figures are provided merely to show example structures.

### DETAILED DESCRIPTION

Techniques are provided herein for selectively thinning the gated channel region of non-planar transistors such as FinFETs and gate-all-around (GAA) transistors. In an example, a middle portion of a fin structure in the gated channel region is thinner, relative to the corresponding end portions of the fin. A gate structure is on the thinned middle portion of the fin, and first and second gate spacers are on the wider respective end portions of the fin. Source and drain regions can be grown or otherwise formed at the end portions. In an example, the selective thinning of the fin is achieved by implanting an implant species within the middle portion of the fin. The implant species modifies surface properties of the fin so as to effectively increase etchability of the implanted fin portions relative to non-implanted fin portions, and thereby enables selective fin shaping in the middle portion during subsequent processing. The end portions receive less or none of the implant species, as they are protected by the gate spacers. In an example, the implant species comprises an element having an atomic mass unit of 80 or less (also referred to herein as a “light element”), such as fluorine, chlorine, argon, boron, arsenic, bromine, nitrogen, silicon (such as amorphous silicon), or halides. The techniques described herein can advantageously be applied to FinFET devices having fins as channel regions, as well as other transistor structures that derive from a fin-like structure, such as gate-all-around devices having nanoribbons or nanowires, or other transistor structures that have a channel region around which the gate structure at least partially wraps. Numerous variations, embodiments, and applications will be apparent in light of the present disclosure.

### General Overview

As device dimensions continue to scale, diminishing dimensions of fins results in short channel effects, where a relatively small channel width contributes to higher resistance between the source or drain region and the channel region, which in turn results in poorer performance of the device. For example, in the case of finFET having epitaxial source and drain regions, a fin extends from the source region to the drain region. Standard scaling of a fin involves a uniform reduction of the width of the entire fin, at the time when the fins are formed. Accordingly, end portions of the fin adjacent to the source or drain regions also have reduced widths, which increases resistance between the fin and the source or drain regions and adversely affects the device performance.

Accordingly, techniques are provided herein to thin a fin selectively, such that gated portions of the fin are scaled or thinned but end portions of the fin adjacent to the source region and the drain regions are not scaled or thinned. Selectively thinning the middle portion of the fin, without correspondingly thinning the end portions, has a number of advantages. For example, the selective thinning of the middle portion improves gate control of the transistor, thereby reducing leakage current. Such selective thinning of the middle portion of fin structure particularly improves transistor performance for low voltage and/or low power applications. Also, because the end portions of the fin in contact with the source and drain regions remain relatively thicker, relatively low resistance between the gated portion of the fin and the source or drain regions is preserved. Moreover, selective thinning of the middle portion may improve lox of the device and/or switching frequency performance at matched off-state leakages, with little or no corresponding penalty on capacitance, gate leakages, reliability metrics, and/or parasitic source-drain resistance. In an example, the selective thinning of a fin is achieved by implanting an implant species within the middle portion of the fin. As further described below, the end portions receive less or none of the implant species. The implant species facilitates a controlled etch of the middle portion of the fin in which the implant species is implanted, by making the middle portion of the fin more responsive (etchable) to a subsequent process, during which at least a portion of the middle portion of the fin is trimmed.

In one embodiment and as described above, the fin has a first end portion abutted to a source region, a second end portion abutted to a drain region, and a middle portion laterally between the first and second end portions. A gate structure is on the middle portion of the fin, a first gate spacer is on the first end portion of the fin, and a second gate spacer is on the second end portion of the fin. An implant species is implanted within middle portion of the fin, and not within the first and second end portions. The implantation may be performed, for example, prior to formation of the final gate structure of the FinFET device. In some such examples, after formation of the fin, the gate spacers, and the source and drain regions, the implant species is implanted within the fin through a sacrificial mask (e.g., polysilicon and/or a dummy gate oxide). If thinning of a first channel region of a first device is desired and thinning of a second channel region of a laterally adjacent second device is not desired, the second channel region may be masked-off when the implant species is implanted within the first channel region of the first device. In any case, the gate spacers on the first and second end portions of the fin prevent or at least reduce implantation of the implant species within the first and second end portions of the fin.

Subsequently, during one or more downstream processes, at least sections of middle portion of the fin is trimmed, wherein the trimming is facilitated by the implant. Example of such one or more downstream processes include a dummy gate removal process. Because the end portions include none or otherwise less of the implant species, the end portions of the fin are substantially largely unaffected during the trim process (or otherwise etch at a much slower rate). After trimming portions of the middle portion of the fin, the final gate structure of the device can be formed. As further described below, due to the selective trimming of the middle fin portion, with less or no trimming of the fin end portions, differences in width, height, and/or tapering of the middle portion of the fin may result, relative to the end portions of the fin. Note that the implant species is distinct from a dopant, which can alter the carrier transport in the channel region. In this sense, the implant species is a non-dopant. In some examples, the middle portion may include a dopant in addition to the implant species, while in other cases the middle portion is devoid of any dopant.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

It should be readily understood that the meaning of “above” and “over” in the present disclosure should be interpreted in the broadest manner such that “above” and “over” not only mean “directly on” something but also include the meaning of over something with an intermediate feature or a layer therebetween. As used herein, the term “backside” generally refers to the area beneath one or more semiconductor devices (below the device layer) either within the device substrate or in the region of the device substrate (in the case where the bulk of the device substrate has been removed). Note that the backside may become a frontside, and vice-versa, if a given structure is flipped. To this end, and as will be appreciated, the use of terms like “above” “below” “beneath” “upper” “lower” “top” and “bottom” are used to facilitate discussion and are not intended to implicate a rigid structure or fixed orientation; rather such terms merely indicate spatial relationships when the structure is in a given orientation.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may be used to detect presence of an implant species within a middle portion of a fin, wherein a concentration of the implant within the middle portion of the fin is at least 10% or at least 50% higher than that within the end portions of the fin. In one embodiment, such tools may also be used to detect differences in width, height, and/or tapering of the middle portion of the fin relative to the end portions of the fin. Numerous configurations and variations will be apparent in light of this disclosure.

### Architecture

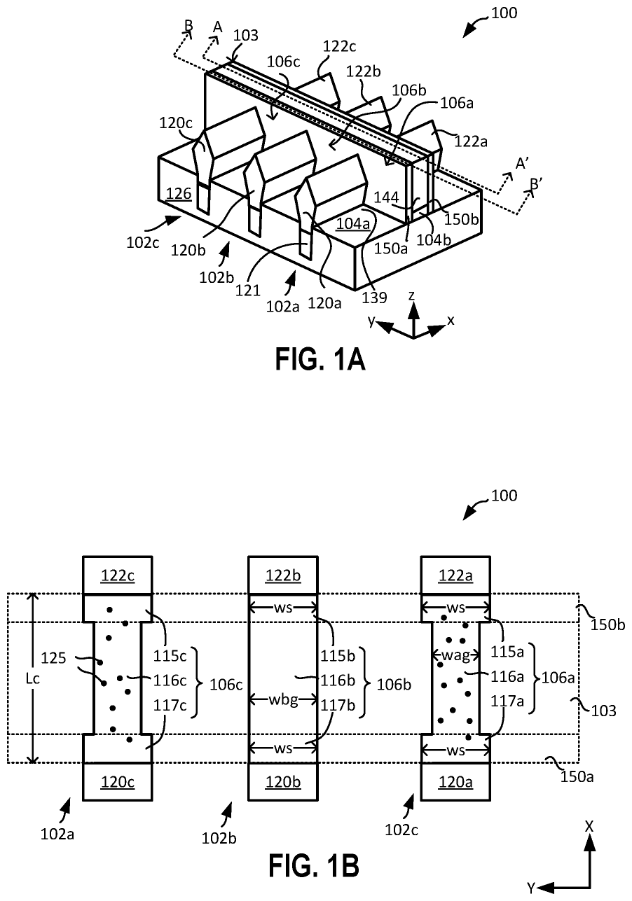

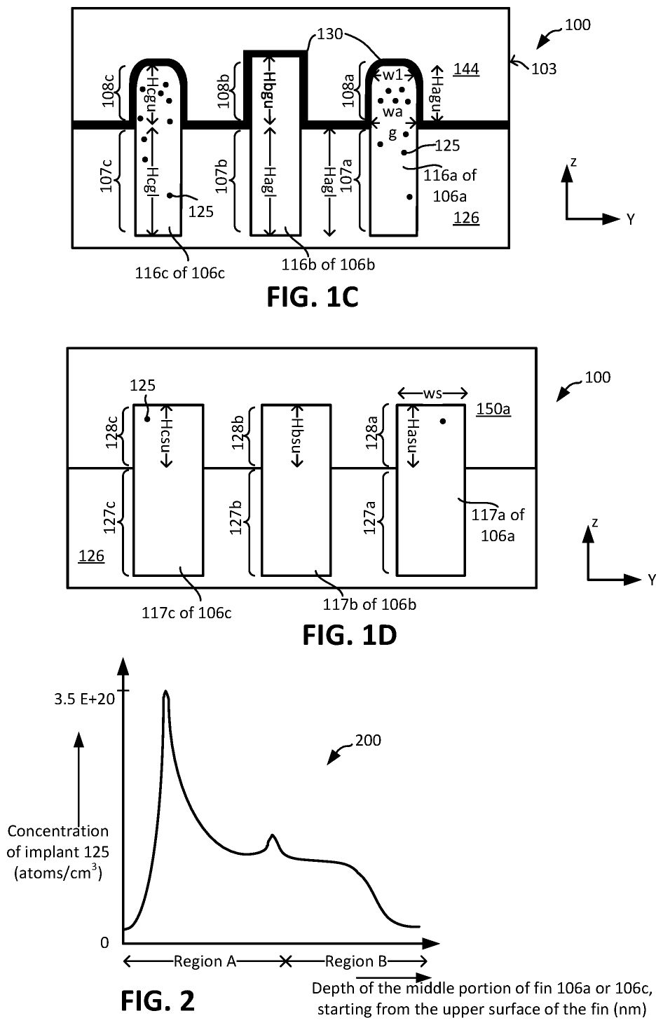

FIGS. 1A, 1B, 1C, and 1D illustrate various views of an integrated circuit (IC) 100 comprising a plurality of devices 102a, 102b, 102c, each device comprising a corresponding fin 106, wherein each fin 106 includes two end portions 115 and 117, and a middle portion 116 between the two end portions 115, 117, wherein the middle portion 116a of at least one fin 106a has a different thickness profile and/or tapering profile compared to the two corresponding end portions 115a, 117a of the at least one fin 106a, and/or wherein the middle portion 116a of the at least one fin 106a is implanted with an implant species 125, in accordance with an embodiment of the present disclosure.

FIG. 1A illustrates a perspective view of the IC 100, and FIG. 1B illustrates a top or plan view of the fins 106a, 106, 106c, with a gate structure 103 and gate spacers 150a, 150b above the fins 106a, 106b, 106c shown as being transparent, such that the fins 106a, 106b, 106c are visible. FIG. 1C illustrates a cross-sectional view of the IC 100 along the line A-A′ of FIG. 1A, and illustrates the fins 106a, 106b, 106c below the gate structure 103. The view of FIG. 1C cuts the IC 100 through the gate structure 103. FIG. 1D illustrates a cross-sectional view of the IC 100 along the line B-B′ of FIG. 1A, and illustrates the fins 106a, 106b, 106c below the gate spacer 150a. The view of FIG. 1D cuts through the gate spacer 150a.

The IC 100 includes three devices 102a, 102b, 102c including the fins 106a, 106b, 106c, respectively. Although three devices including three corresponding fins are illustrated in FIGS. 1A-1D, the IC 100 may include any other number of such devices and any other corresponding number of fins. Note that in FIG. 1A, the labels refer to general locations of the fins 106a, 106b, 106c, as the fins 106a, 106b, 106c are covered by the gate structure 103 and gate spacers 150a, 150b in FIG. 1A.

As illustrated in the plan view of FIG. 1B, each fin 106 comprises end portions 115 and 117, and a middle portion 116 laterally between the end portions 115 and 117. For example, fin 106a comprises end portions 115a, 117a, and middle portion 116a between the end portions 115a, 117a; fin 106b comprises end portions 115b, 117b, and middle portion 116b between the end portions 115b, 117b, and so on.

A gate structure 103 is above and on a middle portion 116 of individual fins 106. For example, the gate structure 103 is above the middle portions 116a, 116b, 116c of fins 106a, 106b, 106c, respectively. Note that in FIG. 1B, the gate structure 103 is illustrated as being transparent, such that the middle portions 116a, 116b, 116c of the fins are visible under the gate structure 103.

A first gate spacer 150a is above and on an end portion 117 of individual fins 106. For example, the gate spacer 150a is above the end portions 117a, 117b, 117c of fins 106a, 106b, 106c, respectively. Note that in FIG. 1B, the gate spacer 150a is illustrated as being transparent, such that the end portions 117a, 117b, 117c of the fins are visible under the gate spacer 150a.

A second gate spacer 150b is above and on an end portion 115 of individual fins 106. For example, the gate spacer 150b is above the end portions 115a, 115b, 115c of fins 106a, 106b, 106c, respectively. Note that in FIG. 1B, the gate spacer 150b is illustrated as being transparent, such that the end portions 115a, 115b, 115c of the fins are visible under the gate spacer 150a.

As can be further seen in FIG. 1B, source and drain regions 120, 122 are on either side of and adjacent to each fin 106. For example, for device 102a, a source region 120a is adjacent to the end portion 117a of the fin 106a, and a drain region 122a is adjacent to the end portion 115a of the fin 106a, such that the fin 106a extends between the source region 120a and the drain region 122a. In an example, the location of the source region 120a and drain region 122a may be interchangeable, and accordingly, the regions 120a, 122a are generally referred to as source or drain (S/D) regions.

Similarly, for device 102b, a S/D region 120b is adjacent to the end portion 117b of the fin 106b, and another S/D region 122b is adjacent to the end portion 115b of the fin 106b, such that the fin 106b extends between the S/D regions 120b and 122b. Similarly, for device 102c, a S/D region 120c is adjacent to the end portion 117c of the fin 106c, and another S/D region 122c is adjacent to the end portion 115c of the fin 106c, such that the fin 106c extends between the S/D regions 120c and 122c.

A length of a fin is measured along the X axis direction in FIGS. 1A-1D. For example, a length Lc of the fin 106c (see FIG. 1B) is measured in the X-axis direction of FIGS. 1A-1D, and between the S/D regions 120c and 122c.

Widths of various sections of a fin are measured in the Y-axis direction of FIGS. 1A-ID, and along a direction perpendicular to the direction in which the length is measured. For example, the width is measured in a direction in which the gate structure 103 extends, which is orthogonal to the direction of the length of a fin 106.

The plan view of FIG. 1B illustrates widths of various portions of the fin 106a, and such description with respect to the widths of the fin 106a also applies to the fin 106c. Note the differences in width profiles of the fins 106a, 106c versus the width profile of the fin 106b, as described below.

Referring to FIG. 1B, each of the end portions 115a, 117a, 115b, 117b, 115c, 117c of the fins 106a, 106b, 106c have a width of ws. Thus, the end portions of each of the fins have substantially the same width (e.g., within a tolerance of at most 0.5 nm or 1 nm). Note that the “s” in the width ws indicates that this is the width of a fin below a gate “spacer” (such as gate spacers 150a, 150b).

The middle portion 116a of the fin 106a has a width of “wag”. Note that the “a” in the width wag indicates that this width is associated with the fin 106a. Also, the “g” in the width wag indicates that this width is for a section of a fin below a “gate” structure (such as gate structure 103). As indicated in FIG. 1B, the width wag of the middle portion 116a of the fin 106a is smaller than the width ws of the end portions 115a, 117a of the fin 106a. Thus, middle portion 116a of the fin 106a is narrower or thinner than each of the end portions 115a, 117a of the fin 106a. In an example, the width wag is smaller than the width ws by at least 3 angstroms, at least 5 angstroms, or at least 8 angstroms, or at least 1 nm, or at least 1.5 nm, or at least 2 nm, for example. Similarly, the middle portion 116c of the fin 106c has a width of “wcg,” which is smaller than the width ws of the end portions 115c, 117c of the fin 106c, e.g., by at least 3 angstroms, at least 5 angstroms, or at least 8 angstroms, or at least 1 nm, or at least 1.5 nm, or at least 2 nm, for example.

Unlike the fins 106a and 106c descried above, in an example, the middle portion 116b of the fin 106b has a width wbg, which is substantially same as the width ws of the end portions 115b, 117b, as illustrated in FIG. 1B.

As described below, the middle portions 116a and 116c of the fins 106a and 106c, respectively, are selectively narrowed or thinned, without narrowing or thinning the middle portion 116b of the fin 106b. Accordingly, as illustrated in FIG. 1B, the width profiles of the middle portions 116a, 116b of the fins 106a and 106b are different from each other. Different fins are not always selectively trimmed and thus all fins can be trimmed globally at once.

As described above, FIG. 1C illustrates a cross-sectional view of the IC 100 along the line A-A′ of FIG. 1A, and illustrates the fins 106a, 106b, 106c below the gate structure 103. Thus, cross-sectional view of the middle portions 116a, 116b, 116c of the fins 106a, 106b, 106c, respectively, are illustrated in FIG. 1C. Thus, in FIG. 1C, the fins 106 extend in the Z-axis or vertical direction. A middle portion 116 of a fin 106 includes a gated portion that is laterally between portions of the gate structure 103, and a subfin portion that is below the gated portion, e.g., see FIGS. 1B and 1C.

The gate structure 103 comprises a gate electrode 144, and a gate dielectric 130 between each fin 106 and the gate electrode 144. The gate dielectric 130 may also be on the bottom surface of the gate trench, as illustrated in FIG. 1C. The gate structure 103 is described in further detail below.

In one embodiment, the middle portion 116 of a fin 106 has an upper region 108, and a lower region 107 below the upper region 108. For example, the middle portion 116a of the fin 106a has an upper region 108a and a lower region 107a, the middle portion 116b of the fin 106b has an upper region 108b and a lower region 107b, and the middle portion 116c of the fin 106c has an upper region 108c and a lower region 107c, as illustrated in FIG. 1C. An upper region 108 of a middle portion 116 of a fin 106 has a corresponding gate structure 103 on at least top and side surfaces thereon. Thus, an upper section of a middle portion 116 of a fin 106, having a corresponding gate structure 103 on at least top and side surfaces thereon, is referred to as the upper region 108 of the middle portion 116 of the fin, and is a gated portion of the fin. The upper region 108 of the middle portion of a fin 106 is laterally between portions of the gate structure 103. The upper region 108 of the middle portion 116 of a fin 106 is also referred to herein as an “active region” or “channel region” of the fin, as this region 108 contributes to conduction of current between a corresponding source region and a corresponding drain region. That is, current is selectively transmitted between a source and drain region through the upper region 108 of the middle portion 116 of the fin. In contrast, the lower region 107 of the middle portion 116 of a fin is a sub-fin area that in below the active region of the fin 106.

The upper regions 108a, 108b, 108c of the fins 106a, 106b, 106c, respectively, have heights of Hagu, Hbgu, and Hegu, respectively. The “g” in the heights Hagu, Hbgu, and Hcgu indicates that the upper regions 108a, 108b, 108c of the fins 106a, 106b, 106c are of the middle portions 116 of the fins 106, and are below the “gate” structure 103. The “u” in the heights Hagu, Hbgu, and Hcgu indicates that these heights are for the “upper” regions 108a, 108b, 108c.

In one embodiment and as illustrated in FIG. 1C, the height Hbgu is greater than the heights Hagu and/or Hegu. For example, as described below, the middle portions 116a, 116c of the fins 106a and 106c, respectively, are selectively trimmed and thinned, resulting in the decrease of the heights Hagu and/or Hcgu. In contrast, the middle portion 116b of the fin 106b is not trimmed and thinned, and hence, the height Hbgu is greater than the heights Hagu and/or Hcgu, e.g., at least 3 angstroms, by at least 5 angstroms, or at least 8 angstroms, or at least 1 nm, or at least 1.5 nm, or at least 2 nm, for example.

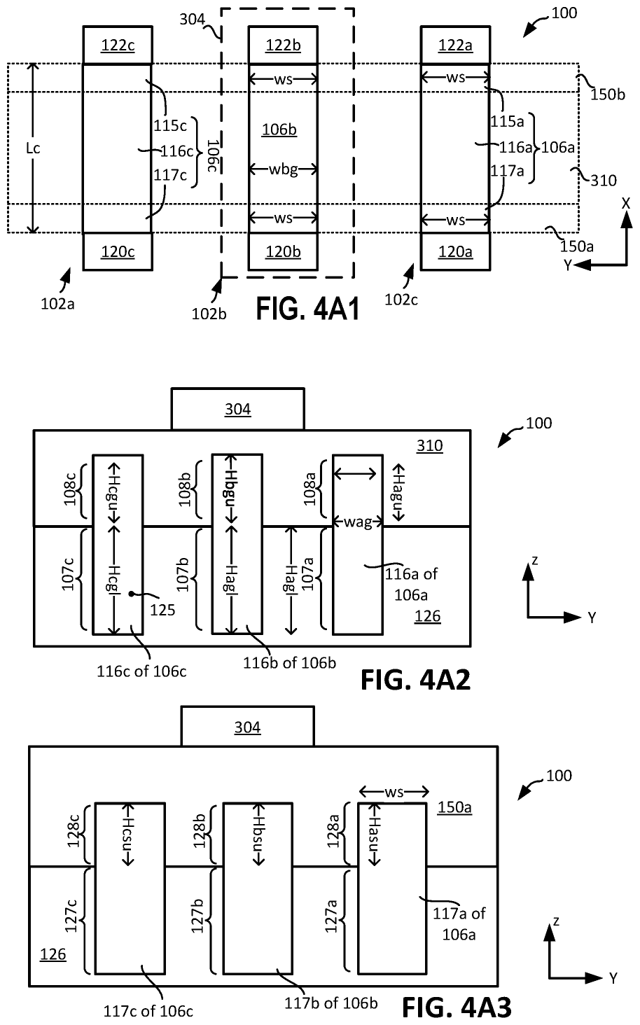

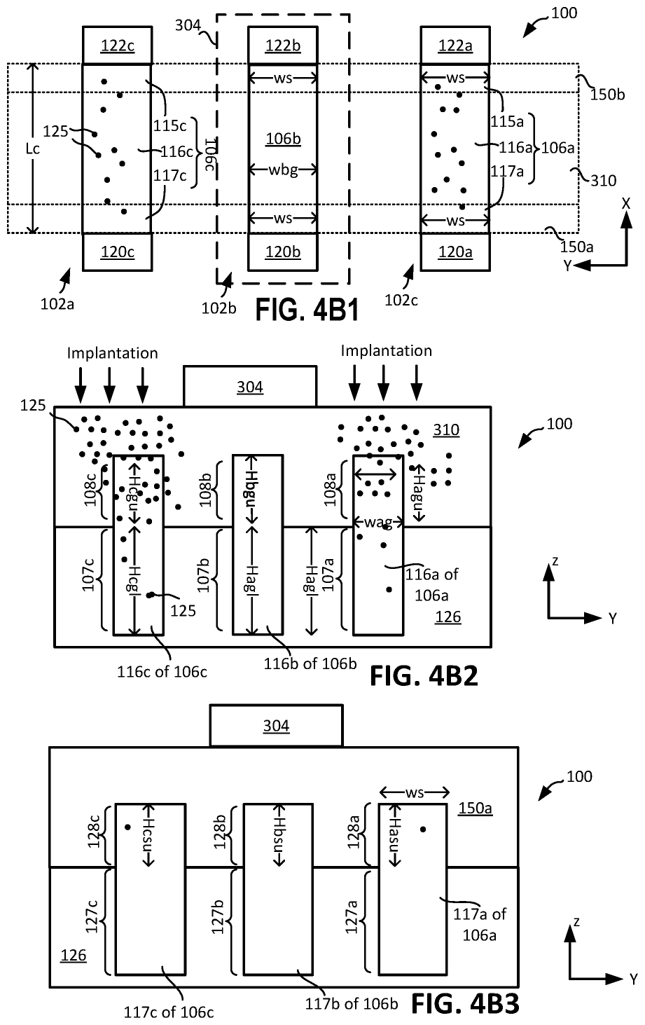

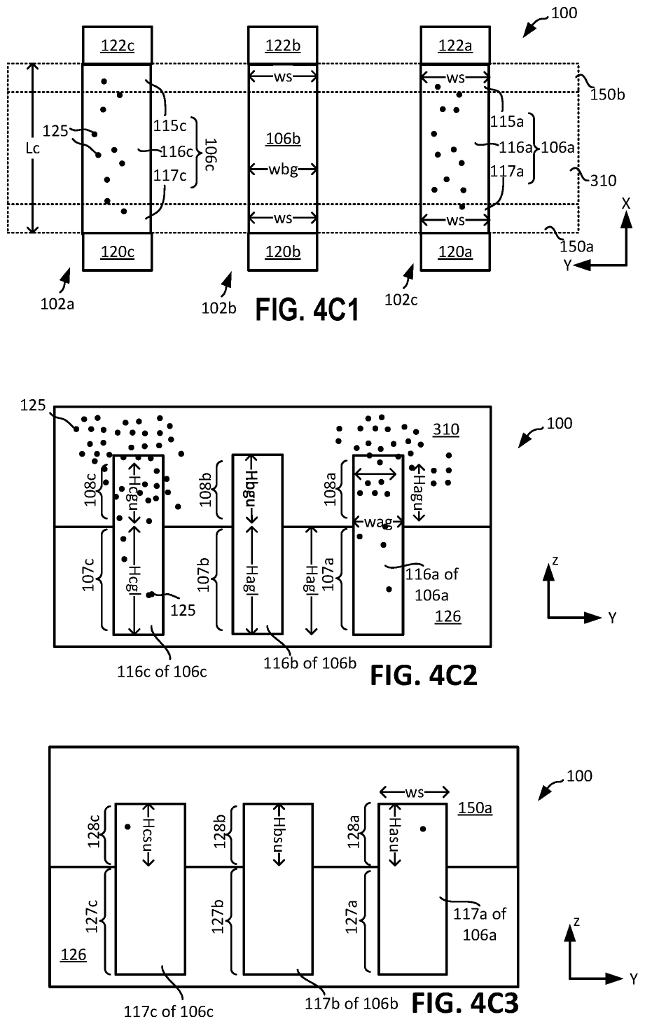

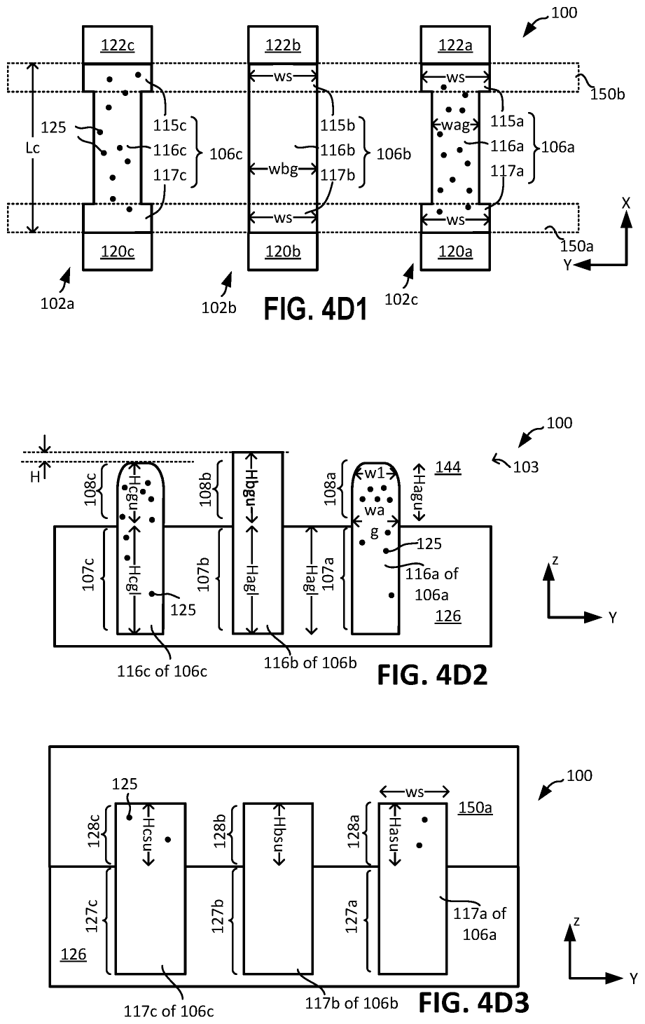

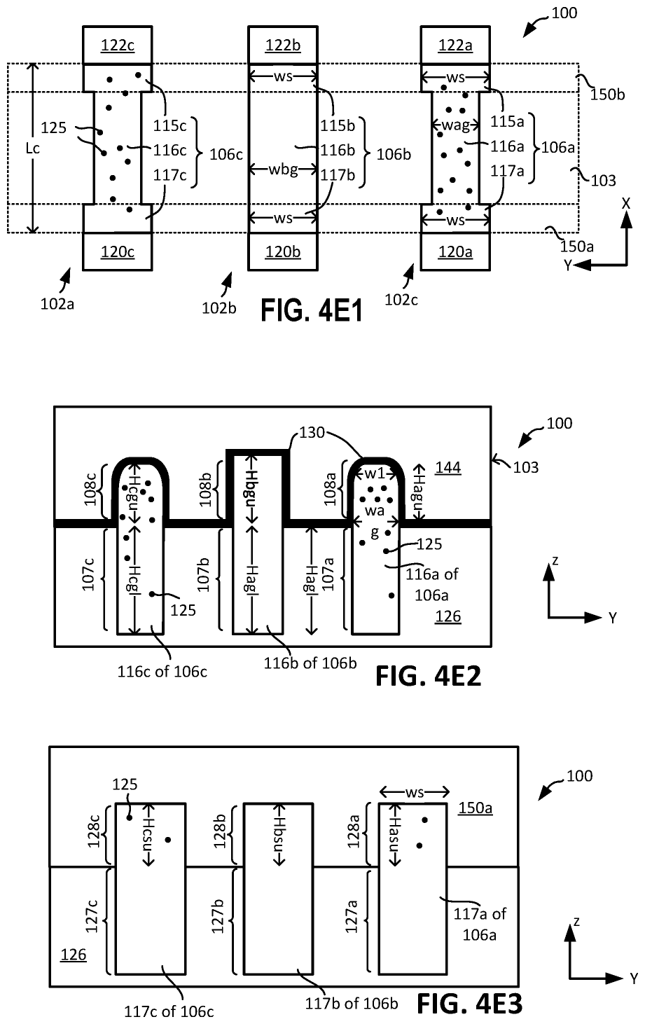

For example, as illustrated in FIG. 4D2 described below, an upper surface of the middle portion 116b of the fin 106b is higher than upper surfaces of the middle portions 116a, 116c of the fins 106a, 116c, e.g., by a vertical distance H, where H is at least 3 angstroms, at least 5 angstroms, or at least 8 angstroms, or at least 1 nm, or at least 1.5 nm, or at least 2 nm, for example.

In one embodiment, because the middle portions 116a, 116c of the fins 106a and 106c, respectively, are selectively trimmed and thinned, each of the upper regions 108a and 108c has a tapered shape. For example, an upper section of the upper region 108a has a width of w1, whereas a lower section of the upper region 108a has a width of wag, as illustrated in FIG. 1C. In an example, the section of the middle portion 116a of the fin 106a having the width wag is also referred to as an intermediate section of the fin 106a, which is a boundary between the upper or gated region 108a and the lower or subfin region 107a. In an example, the width wag is greater than w1 by at least 3 angstroms, or at least 5 angstroms, or at least 8 angstroms, or at least 1 nm, or at least 1.5 nm, or at least 2 nm, for example, which results in the tapered shape of the upper region 108a. The upper region 108c is also similarly tapered. In contrast, in an example, the upper region 108b of the middle portion 116b of the fin 106b may not be tapered.

In an example, the upper region 108a (e.g., which is the gated portion of the fin 106a) is tapered, and the lower region 107a (e.g., which is the sub-fin portion of the fin 106a) is also tapered (although FIG. 1C doesn't illustrate such tapering), and the lower region 107a tapers outward at a greater rate than the above described tapering of the upper region 108a.

FIG. 1D illustrates the cross-sectional view of the IC 100 along the line B-B′ of FIG. 1A, and illustrates the fins 106a, 106b, 106c below the gate spacer 150a. Thus, cross-sectional view of the end portions 117a, 117b, 117c of the fins 106a, 106b, 106c, respectively, are illustrated in FIG. 1D. In FIG. 1D, the fins 106 extend in the Z-axis or vertical direction. The gate spacer 150b is above and on sides of the end portions 117a, 117b, 117c of the fins 106a, 106b, 106c. Note that while FIG. 1D illustrated the end portions 117a, 117b, 117c of the fins 106a, 106b, 106c below the gate spacer 150a, the other end portions 115a, 115b, 115c of the fins 106a, 106b, 106c below the gate spacer 150b may also have a similar structure.

In one embodiment, the end portion 117 of a fin 106 has an upper region 128, and a lower region 127 below the upper region 128. For example, the end portion 117a of the fin 106a has an upper region 128a and a lower region 127a, the end portion 117b of the fin 106b has an upper region 128b and a lower region 127b, and the end portion 117c of the fin 106c has an upper region 128c and a lower region 127c, as illustrated in FIG. 1D. An upper region 128 of an end portion 117 of a fin 106 has a corresponding gate spacer 150a on at least top and side surfaces thereon. The upper region 128 of the end portion 116 of a fin 106 is also the active region or channel region of the fin, as this region 128 contributes to conduction of current between a corresponding source region and a corresponding drain region. That is, current is selectively transmitted between a source and drain region through the upper region 128 of the end portion 117 of the fin. In contrast, the lower region 127 of the end portion 117 of a fin is a sub-fin area that in below the active region of the fin 106.

In one embodiment, the end portions 117a, 117b, 117c of the fins 106a, 106b, 106c are not trimmed or thinned (e.g., protected by the gate spacer 150a during the thinning process). Accordingly, end portions 117a, 117b, 117c of the fins 106a, 106b, 106c have substantially similar height and/or width profile. For example, the upper regions 128a, 128b, 128c of the fins 106a, 106b, 106c, respectively, have heights of Hasu, Hbsu, Hcsu, respectively. The “s” in the heights Hasu, Hbsu, and Hcsu indicates that the upper regions 128a, 128b, 128c are below a gate “spacer” 150a. The “u” in the heights Hasu, Hbsu, and Hcsu indicates that these heights are for the “upper” regions 128a, 128b, 128c. In an example, the heights Hasu, Hbsu, and Hesu are substantially the same, although some differences may exist due to manufacturing variability. In an example, the lower regions 127a, 127b, 127c may also similarly have substantially the same height, although some differences may exist due to manufacturing variability.

In an example, during trimming of the fin 106a, 106c, only the middle portions 115a, 115c of the fins 106a, 106c are trimmed, and end portions 115a, 115c, 117a, 117c of the fins 106a, 106c are not trimmed. Accordingly, in an example, the height Hagu of the upper region of the middle portion 116a of the fin 106a is greater than the height Hasu of the upper region of the end portion 117a of the fin 106a. For example, the middle portion 116a of the fin 106 has a first uppermost surface, the end portion 115a of the fin 106a has a second uppermost surface, and the end portion 117a of the fin 106a has a third uppermost surface, wherein the first uppermost surface is above the second and/or third uppermost surface by at least 3 angstroms, at least 5 angstroms, or at least 8 angstroms, or at least 1 nm, or at least 1.5 nm, or at least 2 nm, for example. For example, the first uppermost surface is at least in part on a first horizontal plane, and the first and third uppermost surface is at least in part on a second horizontal plane, where the first horizontal plane is vertically above the second horizontal plane by at least 3 angstroms, at least 5 angstroms, or at least 8 angstroms, or at least 1 nm, or at least 1.5 nm, or at least 2 nm, for example.

In one embodiment, one or more sections of one or more fins 106 have an implant species 125 implanted therewithin. In an example, the implant species 125 (also referred to herein as implant 125) is implanted within a fin 106 (such as fins 106a, 106c), such that is it relatively easier to selectively trim and thin the fin. For example, in FIGS. 1A-ID, the fins 106a and 106c are implanted within the implant 125, whereas the fin 106b lacks any such implant.

The implant 125 are symbolically illustrated using dots in FIGS. 1B-1D. The number of dots within a given section of a fin is somewhat indicative of relative concentration of the implant 125 within the section (e.g., if a first section has more dots that a second section, this implies that the first section has a higher concentration of the implant 125 than the second section). However, the dots are not indicative of the actual concentration or actual location of the implant 125 within a fin.

As illustrated in FIGS. 1B-1D, the fin 106b is free of the implant 125. The implant 125 are implanted within the fins 106a and 106c, so as to selectively thin and trim the fins 106a, 106c, without thinning and trimming the fin 106b.

In one embodiment, for each of the fins 106a and 106c, a concentration of the implant 125 is higher within a middle portion 116 of the fin, compared to the end portions 115 or 117. For example, the middle portion 116a of the fin 106a has a higher concentration of implant 125 than the end portions 115a, 117a of the fin 106a; and the middle portion 116c of the fin 106c has a higher concentration of implant 125 than the end portions 115c, 117c of the fin 106c. In an example, a concentration of implant 125 within the middle portion of the fins 106a, 106c is greater than a concentration of implant 125 within the end portions of the fins 106a, 106c by at least 10%, or at least 20%, or at least 50%, or at least 80%, or at least 100%, or at least 200%. In an example, the end portions 115a, 117a, 115c, 117c of the fins 106a, 106c lack the implant 125, or has a relatively low concentration of the implant 125, as described above.

An implant concentration for the fin 106a is described below, and such description also applies to the fin 106c. In an example, the implant concentration within the middle portion 116a of the fin 106a varies in the range of 1.0E+19 atoms/cm³ to 5.0E+21 atoms/cm³, or varies in the subrange of 5.0 E+19 atoms/cm³ to 4.0E+20 atoms/cm³.

In one embodiment, a concentration of the implant 125 within the middle portion 116a of the fin 106a varies along a depth of the fin 106a. In general, as described above with respect to FIG. 1C, the upper region 108a of the middle portion 116a of the fin 106a has a higher concentration of the implant than that within the lower region 107a of the middle portion 116a of the fin 106a. Also, recall from above that the implant is distinct from any dopant that may (or may not) be included in the middle portion of fin.

FIG. 2 illustrates a graph 200 depicting a variation of a concentration of implant species 125 along a depth of a middle portion 116a of the fin 106a, in accordance with an embodiment of the present disclosure. The X axis of the graph 200 depicts a depth within the fin. For example, the uppermost surface of the middle portion 116a of the fin 106a has a zero depth, and a lowermost surface of the middle portion 116a of the fin 106a has a highest depth, and the depth of the middle portion 116a of the fin 106a increases along the X axis. For example, region A of the X axis represents the upper region or gated portion 108a (see FIG. 1C) of the middle portion 116a of the fin 106a, which is part of the active channel region of the fin 106a. Region B of the X axis represents the lower region 107a of the middle portion 116a of the fin 106a, which is the sub-fin region of the fin 106a. The Y axis of the graph 200 depicts concentration of the implant 125.

As illustrated in FIG. 2, the average, as well as maximum concentration of the implant 125 is higher in the region A (e.g., the upper region 108a) of the middle portion 116a of the fin 106a than the region B (e.g., the lower region 107a) of the middle portion 116a of the fin 106a. In an example, there is a small peak at the beginning of region B, as the uppermost section of the sub-fin area of the fin (e.g., the region B) may receive some implant from an area marked as 139 in FIG. 1A (e.g., an area not covered by the gate spacers 150a, 150b). In an example, the concentration profile depicted in FIG. 2 may vary from one implementation to the next, and may be based on an implant energy used for the implantation process, along with composition of channel material.

In an example, the implant 125 comprises a halide, such as fluorine, chlorine, or argon. In an example, the implant 125 comprises an element having an atomic mass unit of 80 or less, such as a light element, e.g., fluorine, chlorine, argon, boron, arsenic, bromine, nitrogen, silicon (such as amorphous silicon). In one advantageous embodiment, the implant 125 comprises fluorine.

In one embodiment, implanting the implant 125 within the middle portion 116 of a fin 106 (such as the fins 106a and/or 106c) alters the surface property of the semiconductor material of the fin 106 so as to increase the etch rate of that implanted fin portion, relative to a non-implanted fin portion. As a result, during an etch process, the middle portion 116 of a fin 106 is more amenable to be at least partially thinned (e.g., compared to a middle portion of another fin that has not been implanted with the implants 125). Accordingly, once the middle portions 116a, 116c of the fins 106a, 106c are implanted with the implant 125, the fins 106a, 106b, 106c are exposed to an etch process. Because the fin 106b has not been implanted, the etch process doesn't substantially etch or thin the fin 106b. However, due to presence of the implant 125 within the middle portions 116a, 116c of the fins 106a, 106c, the middle portions 116a, 116c of the fins 106a, 106c are trimmed, as described below.

Note that the implant 125 is implanted primarily or only within the middle portions 116a, 116c of the fins 106a, 106c, and not within the end portions 115a, 115c, 117a, 117c. Accordingly, the selective etch process to trim the middle portions 116a, 116c does not substantially affect the end portions 115a, 115c, 117a, 117c. As a result, the middle portions 116a, 116c are now thinner than the end portions 115a, 115c, 117a, 117c, as illustrated in FIG. 1B. In contrast, because the fin 106b is not implanted, the middle portion 116b and the end portions 115b, 117b of the fin 106b have substantially the same width, as also illustrated in FIG. 1B. In this manner, the selective trimming process can be carried out in a global manner (e.g., whether across the three fins shown in FIG. 1B or some other sub-set of fins, or across a section or block of the wafer, or across the entire wafer), with the implanted fins being trimmed and the non-implanted fins not being trimmed.

Furthermore, due to the trimming of the middle portions 116a, 116c, the upper regions 108a, 108c of the middle portions 116a, 116c of the fins 106a, 106c may be tapered or have rounded corners, such as illustrated in FIG. 1C, with no or less such tapering or rounding occurring for the upper region 108b of the middle portion 116b of the fin 106b. For similar reasons, the height Hagu may be greater than the height Hbgu, as further illustrated in FIG. 1C. Also, because the end portions 115a, 115c, 117a, 117c are not etched, no such tapering or rounding occurs in the upper regions 128a, 128c of the end portions 117a, 117c, as illustrated in FIG. 1D (or to the upper regions of the end portions 115a, 115c).

Thus, referring to the fin 106a (and the same description also applies to the fin 106c), as the middle portion 116a is now thinner (e.g., compared to the end portions 115a, 117a), the channel region corresponding to the fin 106a is scaled. Such selective thinning of the middle portion 116a may help to improve the corresponding transistor's performance, such as improved gate control, lower leakage current, and/or improved performance at low voltage and/or low power. Also, the end portions of the fin 106a in contact with the S/D regions 120a, 122a are not correspondingly thinned, and hence, there is no corresponding increase in parasitic resistance between the fin 106a and S/D regions 120a, 122a due to the fin thinning. Thus, the selective thinning of the middle portion 116a, in an example, may improve on-state current (I_{ON}) of the device 102a and/or switching frequency performance at matched off-state leakage, with little or no corresponding penalty on capacitance, gate leakages, reliability metrics, and/or parasitic source-drain resistance. Note that the fin 106b is not thinned in the example of FIGS. 1A-1D, as such thinning may not be desired for this fin 106b.

Also, in an example, although the implant 125 aids in selective thinning of the fins, the implant 125 does not contribute to, or does not substantially affect the charge present in the channel region of the fins. For example, the doping of the fins is not affected by the implant 125, although in another example, the fins may be doped as well.

In an example, the fins 106 are formed on a substrate and from the substrate, and the fins and the substrate have similar composition. In other embodiments, fins 106 may be formed, grown, or produced by other suitable processes. For example, in some cases, fins 106 may be grown (e.g., epitaxially) from trenches formed in the substrate. In some cases, the fins are of a single semiconductor material. In some other cases, the fins are formed of alternating semiconductor material layers that can be selectively etched with respect to one another, so as to facilitate release of nanoribbons. In a more general sense, the fins can be formed using any suitable techniques. Note that, in some examples, any remaining portion of the substrate below the fins can be removed (e.g., by way of chemical mechanical planarization, or CMP), to facilitate backside processing of the IC 100.

Further note that individual fins 106 may be used for an NMOS, a PMOS, or a CMOS device (e.g., fins of one device may be for an n-type MOSFET and fins of an adjacent device may be for a p-type MOSFET). The fins 106 may comprise any appropriate semiconductor materials used for fins (or nanoribbons, nanowires, or other such semiconductor bodies), such as silicon, silicon germanium, III-V material, and/or other appropriate material used for fins. In an example, sections of the fins may be doped. Any appropriate p-type dopant or an n-type dopant may be used for doping a specific fin, e.g., based on a target application of the fin.

Referring to FIGS. 1A-ID, the gate spacers 150a, 150b are on either side of the gate stack 103, and such the gate spacers 150a, 150b can be used to help determine the channel length and/or to help with replacement gate processes, for example. Gate spacers 150a, 150b may include any suitable dielectric, such as an oxide or a nitride (e.g., silicon oxide, silicon nitride, or silicon oxynitride).

The gate structures 103 comprises a gate stack including gate dielectric 130 and gate electrode 144. As illustrated in FIG. 1C, the gate dielectric 130 separates the gate electrode 144 from the upper regions (or gated regions) 108a, 108b, 108c of the fins 106a, 106b, 106c, respectively. The gate dielectric 130 may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. In some embodiments, the gate dielectric 130 may include one or more silicates (e.g., titanium silicate, tungsten silicate, niobium silicate, and silicates of other transition metals). In some embodiments, an annealing process may be carried out on gate dielectric 130 to improve its quality when high-k dielectric material is used. The gate electrode 130 may include a wide range of materials, such as various suitable metals or metal alloys, such as aluminum, tungsten, titanium, tantalum, ruthenium, or copper, for example. In some embodiments, gate dielectric 130 and/or gate electrode 144 may include a multilayer structure of two or more material layers, for example. For instance, in one embodiment, the gate dielectric 130 includes a first layer of silicon dioxide on the channel region, and a second layer of hafnium oxide on the first layer. The gate electrode 130 may include, for instance, a metal plug along with one or more work function layers, resistance-reducing layers, and/or barrier layers. In some embodiments, gate dielectric 130 and/or gate electrode 144 may include grading (e.g., increasing and/or decreasing) the content/concentration of one or more materials in at least a portion of the feature(s). Note that although the gate dielectric 130 is shown between the gate electrode 144 and the fins 106 in the example embodiment of FIG. C, in other embodiments, the gate dielectric 130 may also be between gate electrode 144 and one or both of gate spacers 150a, 150b, for example. Numerous different gate structure configurations will be apparent in light of this disclosure.

In FIGS. 1A-1B, illustrated are S/D regions 120, 122 on two sides of each fin 106, such that the upper regions 108 and 128 of a fin 106 is laterally between the corresponding S/D regions 120, 122. According to some embodiments, the source and drain regions are epitaxial regions that are provided using an etch-and-replace process. In other embodiments one or more of the source and drain regions could be, for example, implantation-doped native portions of the fins 106 or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. Any semiconductor materials suitable for source and drain regions can be used (e.g., group IV and group III-V semiconductor materials). Also illustrated in FIG. 1A are regions 121 under the source and drain regions, where the regions 121 may be part of the lower regions of the original fins, over which the source and drain regions are formed. Source and drain contacts can be respectively coupled to corresponding source and drain regions, to couple the source and drain regions to outside circuits. The conductive source and drain contacts may be any suitably conductive material, such as a metal or an alloy thereof. Merely as an example, the conductive source and drain contacts includes one or more of tungsten (W), molybdenum (Mo), ruthenium (Ru), copper (Cu), aluminum (Al), titanium (Ti), tantalum (Ta), titanium nitride (TiN), or tantalum nitride (TaN), for example. In some embodiments, the conductive source and drain contacts include one or more of the same metal materials as gate electrode, or a different conductive material.

Although the channel regions in example of FIGS. 1A-ID are fins, the channel regions may comprise other suitable structures, such as gate all around (GAA) structures, e.g., nanoribbons, nanosheets, or nanowires. Note that nanoribbons are used in some example embodiments to describe a GAA structure, but nanowires or other similar semiconductor bodies having any number of height-to-width aspect ratios can be used in a gate-all-around configurations. Thus, in some such examples, a plurality of nanoribbons (or nanosheets or nanowires) may extend between a corresponding source region and a corresponding drain region, where each nanoribbon has a middle portion that is wrapped around by a gate structure, and end portions wrapped around by gate spacers. In an example, the implant 125 may be within the middle portion of individual nanoribbons and not within the end portions of individual nanoribbons, which facilitates thinning of the middle portion of one or more nanoribbons, without any corresponding thinning of the end portions. Thus, the above described benefits of thinning the of the middle portion (and not end portions adjacent to the S/D regions) of the channel region are achieved.

### Methodology

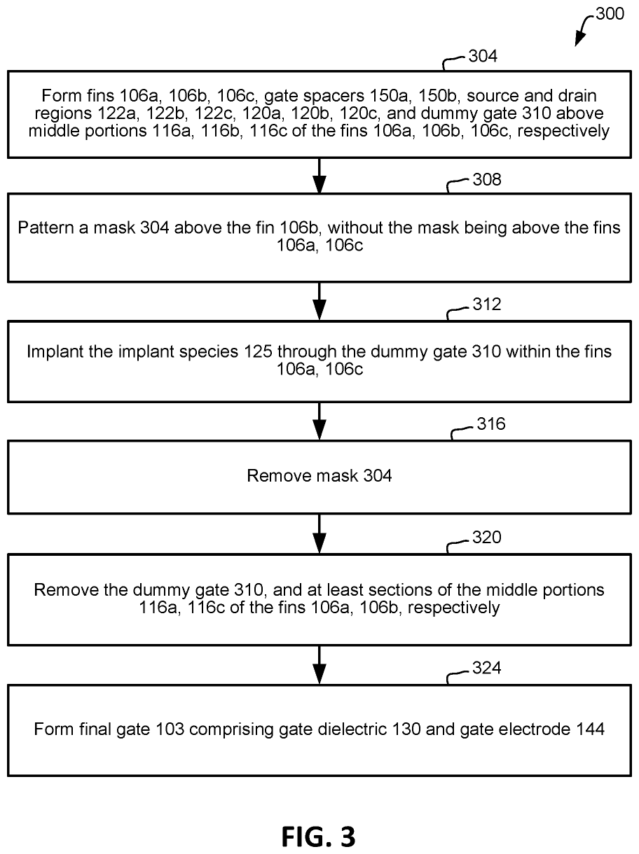

FIG. 3 illustrates a flowchart depicting a method 300 of forming an IC (such as the IC 100 of FIGS. 1A-1D), in accordance with an embodiment of the present disclosure. FIGS. 4A1, 4A2, 4A3, 4B1, 4B2, 4B3, 4C1, 4C2, 4C3, 4D1, 4D2, 4D3, 4E1, 4E2, and 4E3 illustrate various views of an IC (such as the IC 100 of FIGS. 1A-1D) in various stages of processing in accordance with the methodology 300 of FIG. 3, in accordance with an embodiment of the present disclosure. FIGS. 2 and 4A1-4E3 will be discussed in unison.

The views of FIGS. 4A1, 4B1, 4C1, 4D1, and 4E1 are similar to that of FIG. 1B, e.g., is a plan view of the fins 106a-106c, with the gate spacers 150a, 150b, a dummy gate stack 310 comprising a dummy gate material (such as polysilicon or a dummy gate oxide or both), and/or the gate structure 103 shown as being transparent. The cross-sectional views of FIGS. 4A2, 4B2, 4C2, 4D2, and 4E2 are similar to that of FIG. 1C, e.g., along the line A-A′ of FIG. 1A, and illustrate the fins 106a, 106b, 106c below the dummy gate oxide 310 or below the gate structure 103. The cross-sectional views of FIGS. 4A3, 4B3, 4C3, 4D3, and 4E3 are similar to that of FIG. 1D, e.g., along the line B-B′ of FIG. 1A, and illustrate the fins 106a, 106b, 106c below the gate spacer 150a.

Referring to FIG. 3, the method 300 includes, at 304, forming the fins 106a, 106b, 106c, gate spacers 150a, 150b, source and drain regions 122a, 122b, 122c, 120a, 120b, 120c, and dummy gate oxide 310 above middle portions 116a, 116b, 116c of the fins 106a, 106b, 106c, respectively. The formations process 304 can be performed using any appropriate process to form FinFETs, according to an embodiment. The resultant structure is illustrated in FIGS. 4A1, 4A2, 4A3. In FIGS. 4A1, 4A2, 4A3 and the process 304, the final gate structure 103 is not yet formed, and the dummy gate oxide 310 is above the middle portions 116a, 116b, 116c of the fins 106a, 106b, 106c. The dummy gate oxide 310 comprises an appropriate sacrificial material, such as polysilicon, that will be later replaced by the final gate structure 103.

Referring again to FIG. 3, the method 300 proceeds from 304 to 308, where a mask 304 is patterned above the fin 106b, without the mask 304 being above the fins 106a, 106c, e.g., as also illustrated in FIGS. 4A1, 4A2, 4A3. In FIG. 4A1 (and also in FIG. 4B1 described below), the mask 304 is illustrated as being transparent, so that the fin 106b there below is visible. Any appropriate hard mask may be used, such as a carbon based hard mask (CHM) or another type of mask, which can block the implants 125 from reaching the fin 106b in a subsequent process.

Referring again to FIG. 3, the method 300 proceeds from 308 to 312, where the implant species 125 is implanted through the dummy gate oxide 310 and within the fins 106a, 106c, as illustrated in FIGS. 4B1, 4B2, 4B3. In an example, the implant is performed using plasma implantation process or another implantation process. Example implant species have been described above.

As the fin 106b is covered by the mask 304, the implant 125 doesn't reach the fin 106b through the mask 304. Thus, the material of the mask 304 is selected such that the implant 125 doesn't propagate through the mask 304.

However, the dummy gate oxide 310 may include relatively porous material, e.g., through which the implant 125 may propagate and reach the fins 106a, 106c. For example, the implant 125 comprises a relatively light element having an atomic mass unit of 80 or less, as described above. Accordingly, the implant 125 propagates through the relatively porous material of the dummy gate oxide 310, in an example, and reaches the middle portions 116a, 116c of the fins 106a, 106c, respectively, see FIGS. 4B1, 4B2.

However, the gate spacers 150a, 150b are above the end portions 115a, 115b, 117a, 117b, and in an example, the implant 125 cannot propagate through the gate spacers 150a, 150b. Accordingly, in such an example, the implant 125 cannot reach the end portions 115a, 115b, 117a, 117b. Accordingly, as illustrated in FIG. 4B3, the end portions 115a, 115b, 117a, 117b are devoid of the implant 125, or has a relatively lower concentration of the implant 125 (e.g., compared to a concentration in the middle portions 116a, 116c).

The implant 125 is distinct from a dopant that might also be included in one or more of the corresponding channel regions of the fins 106a-c. In some examples, the fins 106a-c are free of any dopants that can alter carrier transport in the channel region. In other examples, the one or more of the fins 106a-c may further comprise, in addition to the implant species, one or more dopants that can alter carrier transport. In this manner, the implant species is a non-dopant that does not alter carrier transport.

Referring again to FIG. 3, the method 300 then proceeds from 312 to 316, where the mask 304 is removed, as illustrated on FIGS. 4C1, 4C2, and 4C3. In an example, the mask 304 is removed using a mask removal process, such as an etch process or an ashing process.

Referring again to FIG. 3, the method 300 then proceeds from 316 to 320, where the dummy gate oxide 310 is removed, and at least sections of the middle portions 116a, 116c of the fins 106a, 106c, respectively are also trimmed, as illustrated in FIGS. 4D1, 4D2, and 4D3. In an example, at least sections of the middle portions 116a, 116c are trimmed using the same removal process as the dummy gate oxide 310 removal process. For example, the dummy gate oxide removal process also trims at least sections of the middle portions 116a, 116c, e.g., using an appropriate etch process. In another example, the dummy gate oxide removal process and the process to trim at least sections of the middle portions of the fins are two different and separate processes.

In an example, as described above, the implant 125 within the middle portions 116a, 116c of the fins 106a, 106c prepares the middle fin surface portions for controlled etch, e.g., compared to the middle portion 116b of the fin 106b which has not been implanted by the implant 125. Accordingly, the subsequent etch process trims at least sections of the middle portions 116a, 116c of the fins 106a, 106c, respectively, without any such trimming of the middle portion 116b of the fin 106b or otherwise at a much higher rate (e.g., more than 10× higher) than any trimming of the middle portion 116b. Accordingly, as illustrated in FIG. 4D1, the middle portions 116a, 116c of the fins 106a, 106c, respectively are thinner than the end portions 115a, 115b, 117a, 117b. In contrast, the non-implanted middle portion 116b is not thinned, as also illustrated in FIG. 4D1.

Similarly, the upper regions 108a, 108c of the middle portions 116a, 116c, respectively, has a tapered shape and has a lower height, e.g., compared to the upper region 116b of the middle portion 116b, as also illustrated in FIG. 4D2, and as described above. For example, as illustrated in FIG. 4D2, an upper surface of the middle portion 116b of the fin 106b is higher than upper surfaces of the middle portions 116a, 116c of the fins 106a, 116c, e.g., by a vertical distance H, where H is at least 3 angstroms, at least 5 angstroms, or at least 8 angstroms, or at least 1 nm, or at least 1.5 nm, or at least 2 nm, for example.

Similarly, in an example, the height Hasu (see FIG. 4D3) is greater than the height Hagu (see FIG. 4D2) by at least 3 angstroms, at least 5 angstroms, or at least 8 angstroms, or at least 1 nm, or at least 1.5 nm, or at least 2 nm, for example. Thus, the upper surface of the end portions 115a, 117a is higher than or above the upper surface of the middle portion 116a of the fin 106a by at least 3 angstroms, at least 5 angstroms, or at least 8 angstroms, or at least 1 nm, or at least 1.5 nm, or at least 2 nm, for example.

Referring again to FIG. 3, the method 300 then proceeds from 320 to 324, where the final gate structure 103 comprising gate dielectric 130 and gate electrode 144 are formed, as illustrated in FIGS. 4E1, 4E2, and 4E3. For example, the gate dielectric 130 is conformally deposited within the gate trench (e.g., that was emptied by removal of the dummy gate oxide 310), such that the gate dielectric 130 is on the middle portions 116a-116c of the fins, on sidewalls of the gate spacers 150a, 150b facing the gate structure 103, and may also be on bottom surface of the gate trench. The gate electrode 144 is then deposited, such that the gate electrode 144 is separated from the fins 106a-106c by the gate dielectric 130. Formation of the final gate structure 103 may be performed using techniques to form final gate structures in FinFET devices.

Note that the processes in method 300 are shown in a particular order for case of description. However, one or more of the processes may be performed in a different order or may not be performed at all (and thus be optional), in accordance with some embodiments.

For example, although FIG. 3 illustrates the implantation process 312 being performed prior to removal of the dummy gate oxide 310, the implantation process 312 may be performed subsequent to the removal of the dummy gate oxide 310 and before formation of the final gate structure 103. Thus, in such an example, after the dummy gate oxide 310 is removed, the implant 125 is implanted selectively within the middle portions 116a, 116c of the fins 106a, 106c (e.g., while the fin 106b is masked by a mask). Subsequent to the implantation, the mask is removed, and the fins are exposed to an etch process, during which at least sections of the middle portions 116a, 116c of the fins 106a, 106c (e.g., which post-implant 125 are now ready for controlled etch) are selectively trimmed. In such an example, the processes 308 and 312 may be performed subsequent to the removal of the dummy gate oxide 310. In an example, the implant 125 may be implanted within the middle portions 116a, 116c of the fins 106a, 106c at any suitable point in time, prior to the formation of the final gate structure 324. Numerous variations on method 300 and the techniques described herein will be apparent in light of this disclosure.

### Example System

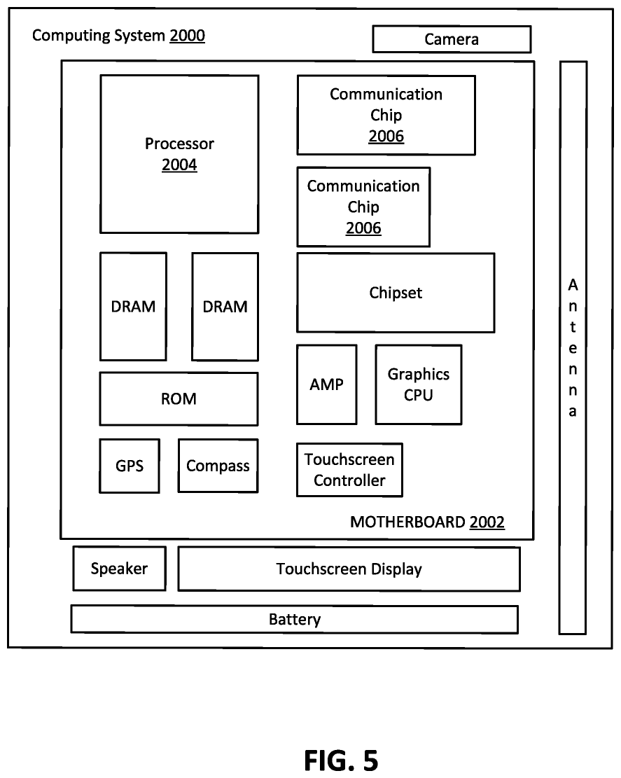

FIG. 5 illustrates a computing system 2000 implemented with integrated circuit structures formed using the techniques disclosed herein, in accordance with some embodiments of the present disclosure. As can be seen, the computing system 2000 houses a motherboard 2002. The motherboard 2002 may include a number of components, including, but not limited to, a processor 2004 and at least one communication chip 2006, each of which can be physically and electrically coupled to the motherboard 2002, or otherwise integrated therein. As will be appreciated, the motherboard 2002 may be, for example, any printed circuit board, whether a main board, a daughterboard mounted on a main board, or the only board of system 2000, etc.

Depending on its applications, computing system 2000 may include one or more other components that may or may not be physically and electrically coupled to the motherboard 2002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 2000 may include one or more integrated circuit structures or devices formed using the disclosed techniques in accordance with an example embodiment. In some embodiments, multiple functions can be integrated into one or more chips (e.g., for instance, note that the communication chip 2006 can be part of or otherwise integrated into the processor 2004).

The communication chip 2006 enables wireless communications for the transfer of data to and from the computing system 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2000 may include a plurality of communication chips 2006. For instance, a first communication chip 2006 may be dedicated to shorter range wireless communications such as Wi-Fi and Bluetooth and a second communication chip 2006 may be dedicated to longer range wireless communications such as GPS, EDGE, GPRS, CDMA, WiMAX, LTE, Ev-DO, and others.

The processor 2004 of the computing system 2000 includes an integrated circuit die packaged within the processor 2004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 2006 also may include an integrated circuit die packaged within the communication chip 2006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 2004 (e.g., where functionality of any chips 2006 is integrated into processor 2004, rather than having separate communication chips). Further note that processor 2004 may be a chip set having such wireless capability. In short, any number of processor 2004 and/or communication chips 2006 can be used. Likewise, any one chip or chip set can have multiple functions integrated therein.

In various implementations, the computing system 2000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following example pertain to further embodiments, from which numerous permutations and configurations will be apparent.

Example 1. An integrated circuit comprising: a source region and a drain region; a body comprising semiconductor material extending from the source region to the drain region, the body having a first end portion adjacent the source region, a second end portion adjacent the drain region, and a middle portion between the first and second end portions, the body further comprising an implant species, wherein a concentration of the implant species in the middle portion of the body is at least 10% higher than a concentration of the implant species in the first and second end portions; a gate structure on the middle portion of the body; and a first gate spacer on the first end portion of the body, and a second gate spacer on the second end portion of the body.

Example 2. The integrated circuit of example 1, wherein the concentration of the implant species in the middle portion of the body is at least 50% higher than the concentration of the implant species in the first and/or second end portions.

Example 3. The integrated circuit of example 1 or 2, wherein at least a section of the first end portion adjacent the source region and/or at least a section of the second end portion adjacent the drain region is devoid of the implant species.

Example 4. The integrated circuit of any one of examples 1-3, wherein the implant species comprises an element having an atomic mass unit of 80 or less.

Example 5. The integrated circuit of any one of examples 1-4, wherein the implant species comprises fluorine, chlorine, argon, or boron.

Example 6. The integrated circuit of any one of examples 1-5, wherein the implant species comprises a halide.

Example 7. The integrated circuit of any one of examples 1-6, wherein the body extends in a first direction from the source region to the drain region, and the gate structure extends in a second direction orthogonal to the first direction, and wherein an upper surface of the middle portion of the body has a first width in the second direction; an upper surface of the first end portion of the body has a second width in the second direction; and the first width is less than the second width by at least 5 angstroms.

Example 8. The integrated circuit of example 7, wherein an upper surface of the second end portion of the body has a third width; and the first width is less than the third width by at least 5 angstroms.

Example 9. The integrated circuit of any one of examples 1-8, wherein the middle portion of the body has a first uppermost surface; and the first end portion of the body has a second uppermost surface that is above the first uppermost surface by at least 1 nm.

Example 10. The integrated circuit of any one of examples 1-9, wherein the body extends in a first direction from the source region to the drain region, and the gate structure extends in a second direction orthogonal to the first direction, and wherein: the middle portion of the body is tapered, such that an uppermost surface of the middle portion of the body has a first width less than a second width of an intermediate region of the middle portion of the body by at least 5 angstroms, wherein the first and second widths are measured in the second direction; and the middle portion of the body is more tapered than any tapering of the first and/or second end portions.

Example 11. The integrated circuit of any one of examples 1-10, wherein the body is a fin.

Example 12. The integrated circuit of any one of examples 1-11, wherein the body includes one of a nanoribbon, a nanowire, or a nanosheet.

Example 13. The integrated circuit of any one of examples 1-12, wherein the middle portion of the body includes a gated portion that is laterally between portions of the gate structure and a subfin portion that is below the gated portion, and the subfin portion tapers outward at a greater rate than the gated portion, and the gated portion of the middle portion tapers outward at a greater rate than each of the first end portion and the second end portion.

Example 14. An integrated circuit comprising: a source region and a drain region; and a body comprising semiconductor material extending between the source region and the drain region, the body having a first end portion, a second end portion, and a middle portion between the first and second end portions, wherein the body further comprises an implant species that includes an element having an atomic mass unit of 80 or less, or a halide, wherein an upper surface of the middle portion has a first width, an upper surface of the first end portion of the body has a second width that is greater than the first width by at least 5 angstroms.

Example 15. The integrated circuit of example 14, further comprising: a gate structure on the middle portion of the body, wherein the body extends in a first direction between the source region and the drain region, and the gate structure extends in a second direction orthogonal to the first direction, and wherein the first and second widths are measured in the second direction; and a first gate spacer on the first end portion of the body, and a second gate spacer on the second end portion of the body.

Example 16. The integrated circuit of example 14 or 15, wherein a concentration of the implant species in the middle portion of the body is at least 50% higher than a concentration of the implant species in the first and second end portions.

Example 17. The integrated circuit of any one of examples 14-16, wherein the implant species comprises fluorine, chlorine, argon, or boron.

Example 18. A method comprising: forming (i) a first body comprising a semiconductor material, the first body having a first end portion, a second end portion, and a middle portion between the first and second end portions, (ii) a second body laterally adjacent to the first body, (iii) a first gate spacer on the first end portion of the first body, and a second gate spacer on the second end portion of the first body, and a dummy gate on the middle portion of the first body, and (iv) a first source or drain region adjacent the first end portion of the first body, and a second source or drain region adjacent the second end portion of the first body; implanting an implant species within the middle portion of the first body, without implanting the implant species within the second body, such that a concentration of the implant species in the middle portion of the body is at least 10% higher than a concentration of the implant species in the first and/or second end portions, wherein the implant species comprises one of an element having an atomic mass unit of 80 or less, or a halide; and forming a gate structure on the middle portion of the first body.

Example 19. The method of example 18, wherein the first body extends in a first direction between the source region and the drain region, and the gate structure extends in a second direction orthogonal to the first direction, and wherein the method further comprises: prior to forming the gate structure, trimming at least the part of the middle portion of first body, such that (i) an upper surface of the middle portion of the first body has a first width in the second direction, (ii) an upper surface of the first end portion of the body has a second width in the second direction, and (iii) the first width is less than the second width by at least 5 angstroms.

Example 20. The method of example 18 or 19, further comprising: patterning a mask that is above the second body, and not above first body, wherein the implanting includes implanting the implant species within the middle portion of the first body, without implanting the implant species within the second body; and removing the mask and at least a part of the first body.

Example 21. The integrated circuit of any one of examples 1 through 17, or the method of any one of examples 18 through 20, wherein the body is free of any dopants that can alter carrier transport.

Example 22. The integrated circuit of any one of examples 1 through 17, or the method of any one of examples 18 through 20, wherein the body comprises one or more dopants that can alter carrier transport.

Example 23. The integrated circuit of any one of examples 1 through 17, 21, or 22, or the method of any one of examples 18 through 20, wherein the implant species is a non-dopant that does not alter carrier transport.

Example 24. The integrated circuit of any one of examples 1 through 17, 21-23, or the method of any one of examples 18 through 20, wherein the concentration of the implant species in the middle portion of the body is at least 15% higher than the concentration of the implant species in the first and/or second end portions, or at least 20% higher, or at least 25% higher, or at least 30% higher, or at least 35% higher, or at least 40% higher, or at least 45% higher, or at least 55% higher, or at least 60% higher, or at least 65% higher, or at least 70% higher, or at least 75% higher, or at least 80% higher, or at least 85% higher, or at least 90% higher, or at least 95% higher, or at least 100% higher.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. An integrated circuit comprising:
a source region and a drain region;
a body comprising semiconductor material extending from the source region to the drain region, the body having a first end portion adjacent the source region, a second end portion adjacent the drain region, and a middle portion between the first and second end portions, the body further comprising an implant species, wherein a concentration of the implant species in the middle portion of the body is at least 10% higher than a concentration of the implant species in the first and second end portions;
a gate structure on the middle portion of the body; and
a first gate spacer on the first end portion of the body, and a second gate spacer on the second end portion of the body.

2. The integrated circuit of claim 1, wherein the concentration of the implant species in the middle portion of the body is at least 50% higher than the concentration of the implant species in the first and/or second end portions.

3. The integrated circuit of claim 1, wherein at least a section of the first end portion adjacent the source region and/or at least a section of the second end portion adjacent the drain region is devoid of the implant species.

4. The integrated circuit of claim 1, wherein the implant species comprises an element having an atomic mass unit of 80 or less.

5. The integrated circuit of claim 1, wherein the implant species comprises fluorine, chlorine, argon, or boron.

6. The integrated circuit of claim 1, wherein the implant species comprises a halide.

7. The integrated circuit of claim 1, wherein the body extends in a first direction from the source region to the drain region, and the gate structure extends in a second direction orthogonal to the first direction, and wherein:
an upper surface of the middle portion of the body has a first width in the second direction;
an upper surface of the first end portion of the body has a second width in the second direction; and
the first width is less than the second width by at least 5 angstroms.

8. The integrated circuit of claim 7, wherein:
an upper surface of the second end portion of the body has a third width; and
the first width is less than the third width by at least 5 angstroms.

9. The integrated circuit of claim 1, wherein:
the middle portion of the body has a first uppermost surface; and
the first end portion of the body has a second uppermost surface that is above the first uppermost surface by at least 1 nm.

10. The integrated circuit of claim 1, wherein the body extends in a first direction from the source region to the drain region, and the gate structure extends in a second direction orthogonal to the first direction, and wherein:
the middle portion of the body is tapered, such that an uppermost surface of the middle portion of the body has a first width less than a second width of an intermediate region of the middle portion of the body by at least 5 angstroms, wherein the first and second widths are measured in the second direction; and
the middle portion of the body is more tapered than any tapering of the first and/or second end portions.

11. The integrated circuit of claim 1, wherein the body is a fin.

12. The integrated circuit of claim 1, wherein the body includes one of a nanoribbon, a nanowire, or a nanosheet.

13. The integrated circuit of claim 1, wherein the middle portion of the body includes a gated portion that is laterally between portions of the gate structure and a subfin portion that is below the gated portion, and the subfin portion tapers outward at a greater rate than the gated portion, and the gated portion of the middle portion tapers outward at a greater rate than each of the first end portion and the second end portion.

14. The integrated circuit of any claim 1, wherein the implant species is a non-dopant that does not alter carrier transport.

15. An integrated circuit comprising:
a source region and a drain region; and
a body comprising semiconductor material extending between the source region and the drain region, the body having a first end portion, a second end portion, and a middle portion between the first and second end portions, wherein the body further comprises an implant species that includes an element having an atomic mass unit of 80 or less, or a halide, wherein an upper surface of the middle portion has a first width, an upper surface of the first end portion of the body has a second width that is greater than the first width by at least 5 angstroms.

16. The integrated circuit of claim 15, further comprising:
a gate structure on the middle portion of the body, wherein the body extends in a first direction between the source region and the drain region, and the gate structure extends in a second direction orthogonal to the first direction, and wherein the first and second widths are measured in the second direction; and
a first gate spacer on the first end portion of the body, and a second gate spacer on the second end portion of the body.

17. The integrated circuit of claim 15, wherein a concentration of the implant species in the middle portion of the body is at least 50% higher than a concentration of the implant species in the first and second end portions.

18. The integrated circuit of claim 15, wherein the implant species comprises fluorine, chlorine, argon, or boron.

19. A method comprising:
forming (i) a first body comprising a semiconductor material, the first body having a first end portion, a second end portion, and a middle portion between the first and second end portions, (ii) a second body laterally adjacent to the first body, (iii) a first gate spacer on the first end portion of the first body, and a second gate spacer on the second end portion of the first body, and a dummy gate on the middle portion of the first body, and (iv) a first source or drain region adjacent the first end portion of the first body, and a second source or drain region adjacent the second end portion of the first body;
implanting an implant species within the middle portion of the first body, without implanting the implant species within the second body, such that a concentration of the implant species in the middle portion of the body is at least 10% higher than a concentration of the implant species in the first and/or second end portions, wherein the implant species comprises one of an element having an atomic mass unit of 80 or less, or a halide; and
forming a gate structure on the middle portion of the first body.

20. The method of claim 19, wherein the first body extends in a first direction between the source region and the drain region, and the gate structure extends in a second direction orthogonal to the first direction, and wherein the method further comprises:
prior to forming the gate structure, trimming at least the part of the middle portion of first body, such that (i) an upper surface of the middle portion of the first body has a first width in the second direction, (ii) an upper surface of the first end portion of the body has a second width in the second direction, and (iii) the first width is less than the second width by at least 5 angstroms.
